(19) United States
(12) Patent Application Publication
(10) Pub. No.: US 2017/0345912 A1
(43) Pub. Date: Nov. 30, 2017

(54) METHODS OF RECESSING A GATE STRUCTURE USING OXIDIZING TREATMENTS DURING A RECESSING ETCH PROCESS

(71) Applicant: GLOBALFOUNDRIES Inc., Grand Cayman (KY)

(72) Inventor: Helios Hyun Jae Kim, Gansevoort, NY (US)

(21) Appl. No.: 15/165,014

(22) Filed: May 26, 2016

(51) Int. Cl. H01L 29/66; H01L 21/28

(52) U.S. Cl. CPC H01L 29/66545; H01L 21/28088

(57) ABSTRACT

A method includes forming a gate structure embedded in a dielectric layer above a substrate. A first recessing etch process is performed to remove a first portion of the gate structure. An oxidizing treatment is performed to oxidize a second portion of the gate structure after removing the first portion. A second recessing etch process is performed to remove at least the second portion to define a cap recess in the dielectric layer above the gate structure. A cap layer is formed in the cap recess.

### BACKGROUND OF THE INVENTION

### 1. Field of the Invention

The present disclosure generally relates to the fabrication of integrated circuits, and, more particularly, to various methods of recessing a gate structure using an oxidizing treatment during a recessing etch process.

### 2. Description of the Related Art

In modern integrated circuit products, such as microprocessors, storage devices and the like, a very large number of circuit elements, especially transistors, are formed on a restricted chip area. In integrated circuits fabricated using metal-oxide-semiconductor (MOS) technology, field effect transistors (FETs) (both NMOS and PMOS transistors) are provided that are typically operated in a switching mode. That is, these transistor devices exhibit a highly conductive state (ON-state) and a high impedance state (OFF-state). FETs may take a variety of forms and configurations. For example, among other configurations, FETs may be either so-called planar FET devices or three-dimensional (3D) devices, such as FinFET devices.

A field effect transistor (FET), irrespective of whether an NMOS transistor or a PMOS transistor is considered, and irrespective of whether it is a planar or 3D FinFET device, typically comprises a doped source region and a separate doped drain region that are formed in a semiconductor substrate. The source and drain regions are separated by a channel region. A gate insulation layer is positioned above the channel region and a conductive gate electrode is positioned above the gate insulation layer. The gate insulation layer and the gate electrode may sometimes be referred to as the gate structure of the device. By applying an appropriate voltage to the gate electrode, the channel region becomes conductive and current is allowed to flow from the source region to the drain region. The gate structures for such planar FET devices may be manufactured using so-called “gate-first” or “replacement gate” (gate-last) manufacturing techniques.

Typically, due to the large number of circuit elements, e.g., transistors, and the required complex layout of modern integrated circuits, the electrical connections of the individual circuit elements cannot be established within the same device level on which the circuit elements are manufactured, but require one or more additional metallization layers, which generally include metal-containing lines providing the intra-level electrical connection, and also include a plurality of inter-level connections or vertical connections, which are also referred to as vias. These vertical interconnect structures comprise an appropriate metal and provide the electrical connection of the various stacked metallization layers.

Furthermore, in order to actually connect the circuit elements, i.e., the transistors, with the metallization layers, an appropriate vertical contact structure to the transistor device is formed, wherein a first end of the vertical contact structure is connected to a respective contact region of a circuit element, such as a gate electrode and/or the drain and source regions of transistors, and a second end that is connected to a respective metal line in the metallization layer by a conductive via. As device dimensions have decreased, and packing densities have increased, the physical space between adjacent gate structures is so small that it is very difficult to accurately position, align and form a contact opening in a layer of insulating material using traditional masking and etching techniques. Accordingly, contact-formation technologies have been developed in which contact openings are formed in a self-aligned manner by removing dielectric material, such as silicon dioxide, selectively from the spaces between closely spaced gate electrode structures. That is, after completing the transistor structures, the gate cap layer and the sidewall spacers of adjacent gate structures are effectively used as etch masks for selectively removing the silicon dioxide material in order to expose the source/drain regions of the transistors, thereby providing self-aligned trenches which are substantially laterally defined by the spacer structures positioned adjacent the gate structures.

However, the aforementioned process of forming self-aligned contacts results in an undesirable loss of the materials that protect the conductive gate electrode, i.e., the gate cap layer and the sidewall spacers, as will be explained with reference to FIGS. 1A-1B. FIG. 1A schematically illustrates a cross-sectional view of an integrated circuit product 100 at an advanced manufacturing stage. As illustrated, the product 100 comprises a plurality of illustrative gate structures 105 that are formed above a substrate 110, such as a silicon substrate. The gate structures 105 are comprised of an illustrative gate insulation layer 115 and an illustrative gate electrode 120 that are formed in a gate cavity 125 using a gate-last processing technique, an illustrative gate cap layer 130 and sidewall spacers 135. The gate cap layer 130 and sidewall spacers 135 encapsulate and protect the gate electrode 120 and the gate insulation layer 115. Also depicted in FIG. 1A are a plurality of raised source/drain regions 140 and a layer of insulating material 145, e.g., silicon dioxide.

FIG. 1B depicts the product 100 after a contact etching process was performed to form a contact opening 150 in the layer of insulating material 145 for a self-aligned contact. Although the contact etch process performed to form the opening 150 is primarily directed at removing the desired portions of the layer of insulating material 145, portions of the protective gate cap layer 130 and the protective sidewall spacers 135 are consumed during the contact etch process, as simplistically depicted in the dashed-line regions 155. Typically, when the layer of insulating material 145 is made of silicon dioxide, and the spacers 135 and gate cap layer 130 are made of silicon nitride, the contact etching process may be a dry, anisotropic (directional) plasma etching process that is intended to selectively remove the silicon dioxide layer 145 relative to the silicon nitride spacers 135/gate cap layer 130 of the gate structure 105. As device dimensions continue to shrink, the process margin for such a dry etching process is reduced. For example, if sufficient thickness of the spacers 135 is lost during the contact etching process, then the resulting device 100 may not be acceptable in that many device specifications specify that, after the contact etching process is performed, the final spacer must have a minimum thickness or width. If the gate electrode 120 is exposed, a contact-to-gate short will be introduced, resulting in a defective device 100.

The problems associated with the erosion of the gate cap layer 130 and the spacers 135 may be exacerbated by variations in the height of the gate electrode 120 and the thickness of the cap layer 130. Different transistors on the same product may have different gate lengths. In addition, the gate profile (i.e., top CD versus bottom CD) may vary due to process variations. The gate length and profile affect the aspect ratio of the gate cavity. In turn, the aspect ratio affects the replacement gate metal deposition and subsequent timed recess etch that makes room for the gate cap layer. As a result of these sources of variation, not all of the gate electrodes 120 may have the same height and not all of the gate cap layers 130 may have the same thickness.

One technique for reducing the likelihood of exposing the gate electrode during a self-aligned contact etch is to recess the gate electrode and form a cap layer with a greater thickness. In general, gate structures may be formed using a replacement technique, where a sacrificial gate material is formed and later replaced with a metal gate structure.

FIG. 1C illustrates a more detailed view of a gate structure 105 in the product 100 prior to the self-aligned contact etch of FIG. 1B. FIG. 1C illustrates the device 100 after a replacement gate structure 160 is formed. The replacement gate structure 160 includes a gate dielectric layer 165 (e.g., a high-k dielectric material), a work function material (WFM) layer 170 or stack of WFM layers, and a fill layer 180 (e.g., tungsten). Due to the high aspect ratio of the gate cavity in which the replacement gate structure 160 was formed, a void 185 may be present when the fill material is formed. As a result of the different materials in the replacement gate structure 160 and the possible void 185, when the gate structure 160 is recessed to make room for a thicker cap layer 190 (FIG. 1D), the middle region of the gate structure 160 may be etched at a faster rate, leaving stringers 195 on the sidewalls of the cavity, as illustrated in FIG. 1D. The presence of the stringers 195 increases the likelihood of a contact to gate short.

The present disclosure is directed to various methods of forming contact structures on semiconductor devices and the resulting semiconductor devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of recessing a gate structure using an oxidizing treatment during a recessing etch process. One method disclosed herein includes, among other things, forming a gate structure embedded in a dielectric layer above a substrate. A first recessing etch process is performed to remove a first portion of the gate structure. An oxidizing treatment is performed to oxidize a second portion of the gate structure after removing the first portion. A second recessing etch process is performed to remove at least the second portion to define a cap recess in the dielectric layer above the gate structure. A cap layer is formed in the cap recess.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1D depict one illustrative prior art method of forming self-aligned contacts and some of the problems that may be encountered using such prior art processing techniques; and

FIGS. 2A-2F depict various illustrative methods disclosed for recessing a gate structure using an oxidizing treatment during a recessing etch process.

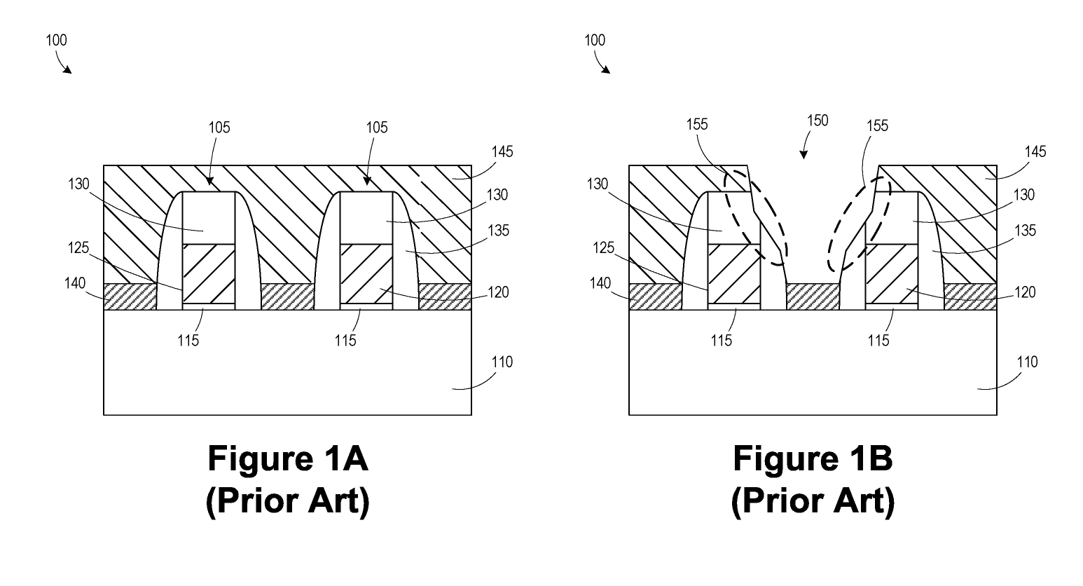

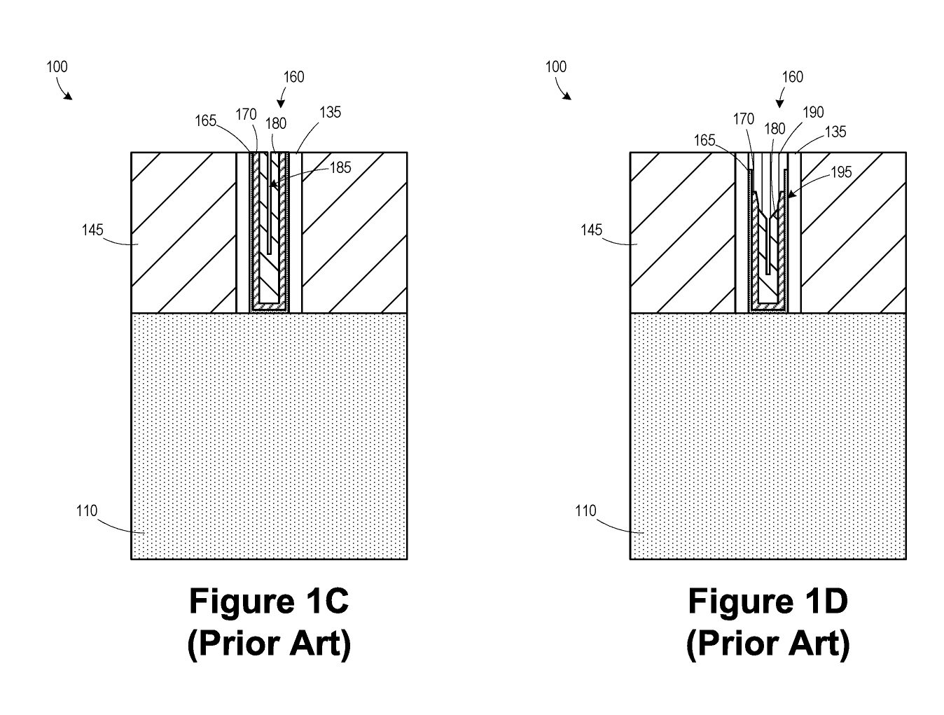

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various methods of recessing a gate structure using an oxidizing treatment during a recessing etch process. Moreover, as will be readily apparent to those skilled in the art upon a complete reading of the present application, the present method is applicable to a variety of devices, including, but not limited to, planar transistor devices, FinFET devices, nanowire devices, and the methods disclosed herein may be employed to form N-type or P-type semiconductor devices. The methods and devices disclosed herein may be employed in manufacturing products using a variety of technologies, e.g., NMOS, PMOS, CMOS, etc., and they may be employed in manufacturing a variety of different products, e.g., memory products, logic products, ASICs, etc. Of course, the inventions disclosed herein should not be considered to be limited to the illustrative examples depicted and described herein. With reference to the attached figures, various illustrative embodiments of the methods and devices disclosed herein will now be described in more detail.

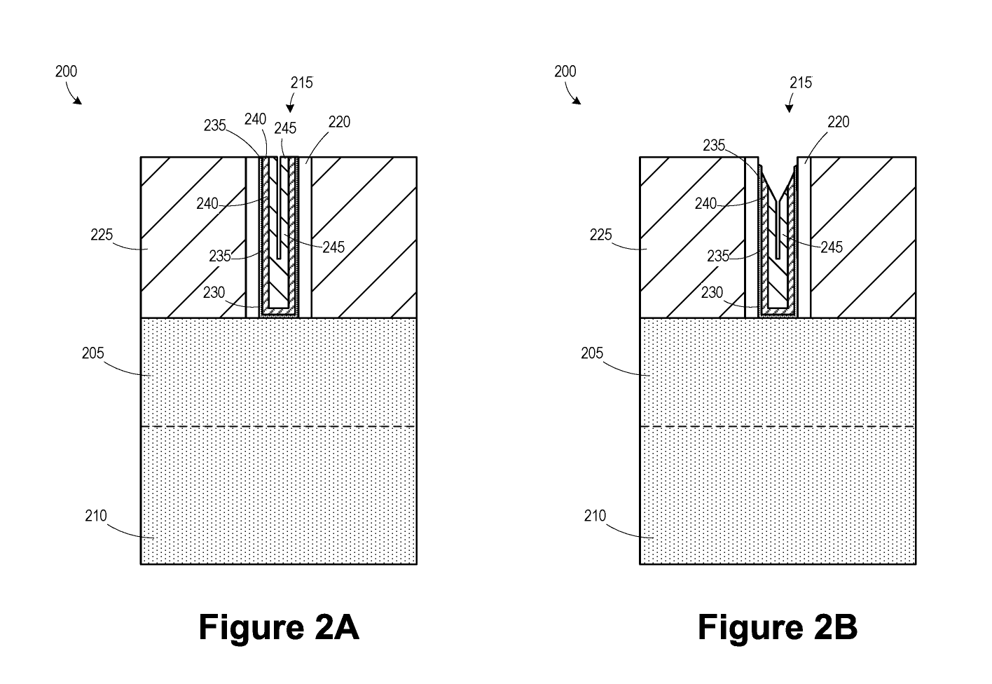

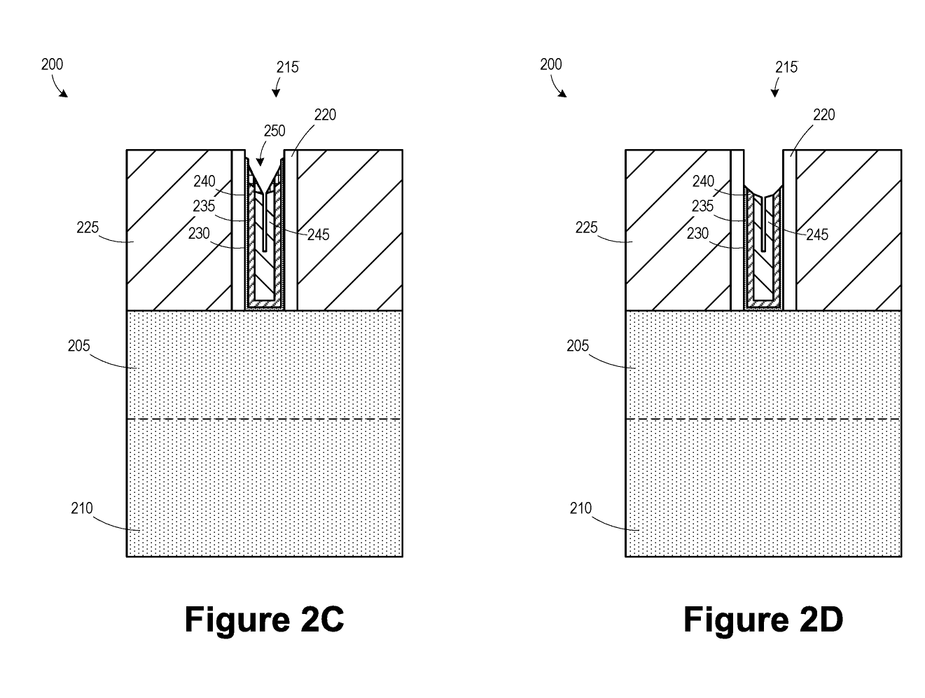

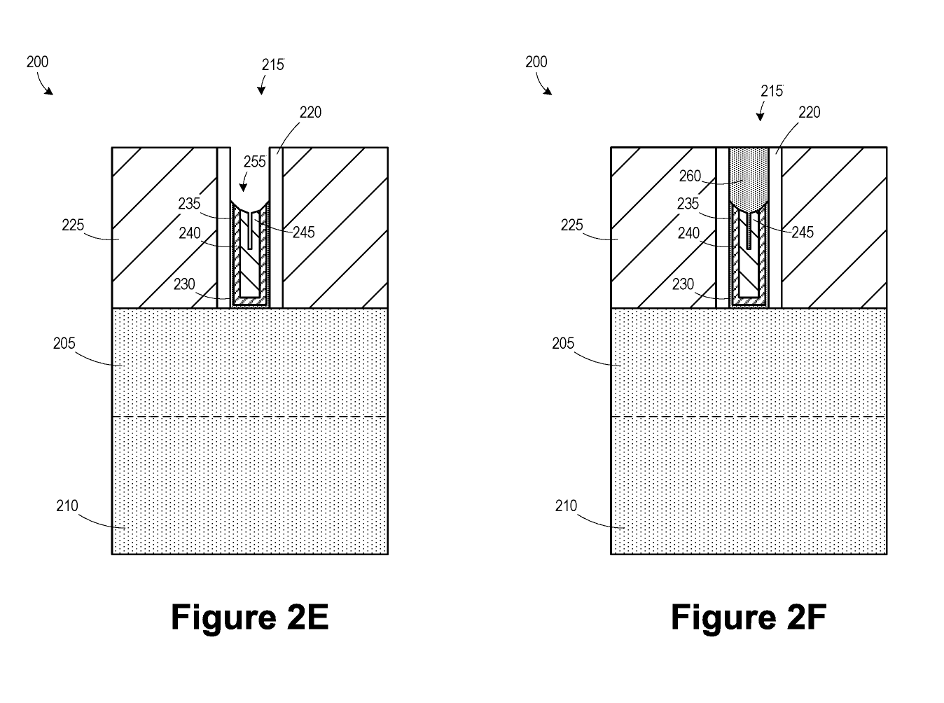

FIGS. 2A-2F illustrate various illustrative methods disclosed herein for forming an integrated circuit product 200. In the illustrated embodiment, the product includes finFET transistor devices, but the techniques described herein are not so limited, and they may be applied to other types of devices, such as planar devices. FIGS. 2A-2F show a cross-sectional view of the product 200 taken through the long axis of one of a first fin 205 formed in a substrate 210. The cross-sectional view is taken in a direction corresponding to the gate length direction of the product 200. An epitaxial growth process may be performed to provide different materials for the fin 205 as compared to the substrate 210. For example, the fin 205 may include boron doped SiGe (e.g., for a PFET) or phosphorus doped Si (e.g., for an NFET).

The transistor devices formed in the product 200 depicted herein may be either NMOS or PMOS transistors, or a combination of both. Additionally, various doped regions, e.g., source and drain regions, halo implant regions, well regions and the like, may be formed, but are not depicted in the attached drawings. The substrate 210 may have a variety of configurations, such as the depicted bulk silicon configuration. The substrate 210 may also have a silicon-on-insulator (SOI) configuration that includes a bulk silicon layer, a buried insulation layer and an active layer, wherein semiconductor devices are formed in and above the active layer. The substrate 210 may be formed of silicon or silicon germanium or it may be made of materials other than silicon, such as germanium. Thus, the terms “substrate” or “semiconductor substrate” should be understood to cover all semiconducting materials and all forms of such materials. The substrate 210 may have different layers. For example, the fin 205 may be formed in a process layer formed above the base layer of the substrate 210.

In the illustrated embodiment, a replacement gate technique was used to form a gate structure 215 in the product 200. A placeholder gate structure (not shown) was formed, and spacers 220 (e.g., silicon nitride) were formed adjacent the sacrificial gate structure. A dielectric layer 225 was formed above the sacrificial gate structure and planarized. In the illustrated embodiment, the dielectric layer 225 may be silicon dioxide, a low-k dielectric material having a dielectric constant of approximately 3.0 or lower or an ultra-low-k (ULK) material having a dielectric constant of approximately 2.5 or lower. The sacrificial gate structure was removed and the replacement gate structure 215 was formed in the resulting gate cavity 230.

A gate dielectric layer 235 (e.g., a high-k material, such as doped or undoped hafnium oxide) was formed in the cavity 230. A work function material (WFM) layer 240 was formed above the gate dielectric layer 235. In the illustrated embodiment, the work function material layer 240 includes a stack of layers, such as TiN/TiAlC/TiN. In some embodiments, the stack of layers may include other material between the TiN layers, such as titanium carbide, titanium aluminum or tantalum silicide. A conductive material layer 245 (e.g., tungsten, cobalt, aluminum) was formed above the work function material 240 to fill the remainder of the gate cavity. Subsequently, a planarization process was performed to remove excess portions of the conductive material layer 245 and excess amounts of the other layers 235, 240 extending outside the gate cavity and above the upper surface of the dielectric layer 225.

A multiple step etching process is performed to recess the gate structure 215 and reduce the presence of stringers. In general, the etch process includes iterative etching and oxidizing steps that etch the stringers.

FIG. 2B illustrates the product 200 after a first recessing etch process was performed to recess the gate structure 215. In some embodiments, the first recessing etch process is a bulk etch process using plasma including phases of Ar/Cl₂ and/or Cl₂/BCl₃ to recess the conductive material layer 245 and the WFM layer 240. Example etch parameters include Ar 80-120 mL/min/Cl₂ 5-120 mL/min or Cl₂ 5-30 mL/min/BCl₃ 150-250 mL/min with an RF bias. In some embodiments, an unbiased Cl₂/BCl₃ phase may be employed. The Cl₂/BCl₃ phase also recesses the gate dielectric layer 235.

FIG. 2C illustrates the product 200 after an oxidizing plasma treatment was performed to form an oxidized region 250 on the gate structure 215. The oxidizing plasma treatment includes oxygen and chlorine. Example plasma parameters include O₂ 5-20 mL/min/Cl₂ 150-250 mL/min. The oxygen component oxidizes the metal surfaces, and thereby the stringer associated with the conductive material layer 245. The chlorine component oxidizes the stringer associated with the WFM layer 240.

FIG. 2D illustrates the product 200 after the recessing etch process was continued (e.g., with the Cl₂/BCl₃ plasma and a bias power) to remove the oxidized region 250 and additional portions of the WFM layer 240 and the conductive material layer 245. During the etch process, the bias power also facilitates etching of the gate dielectric layer 235. Note that the recessing etch process does not proceed along a uniform etch front, so the stringers tend to become more pronounced during the recessing etch process.

The oxidizing and etch cycles are repeated to recess the gate structure 215 and reduce the presence of any stringers. In one embodiment, the oxidizing plasma treatment is performed approximately four to fifteen times during the etch process. In some embodiments, the recessing etch process may include alternative reactants. For example, a N₂/O₂/NF₃ plasma may also be employed to recess the conductive material layer 245. In one embodiment, such a plasma is employed after the final oxidizing treatment to set the final height of the conductive material layer 245.

FIG. 2E illustrates the product 200 after the iterative cycles of the recessing etch process and the oxidizing plasma treatments were performed to define a cap recess 255. The oxidizing plasma treatments allow the gate structure 215 to be recessed along a more uniform etch front as compared to recessing etching without the oxidizing plasma treatments.

FIG. 2F illustrates the product 200 after a plurality of processes was performed. A deposition process was performed to deposit a cap layer 260 to fill the recess 255. A planarization process was performed to remove portions of the cap layer 260 extending above the dielectric material 225 outside the cap recess 255.

Additional processing may be performed to complete fabrication of the product 200. For example, a self-aligned contact etch may be performed. The additional margin created due to the removal of the stringers in the gate structure reduces the likelihood of contact-to-gate shorts. Additional metallization layers may be formed to facilitate interconnections and routing.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method, comprising:
forming a gate structure embedded in a dielectric layer above a substrate;
performing a first recessing etch process to remove a first portion of said gate structure;
performing an oxidizing treatment to oxidize a second portion of said gate structure after removing said first portion;
performing a second recessing etch process to remove at least said second portion to define a cap recess in said dielectric layer above said gate structure; and
forming a cap layer in said cap recess.

2. The method of claim 1, further comprising repeating said oxidizing treatment and said second recessing etch process to increase a depth of said cap recess.

3. The method of claim 2, further comprising performing a third recessing etch process to remove a third portion of said gate structure using a plasma comprising N₂, O₂, and NF₃ after performing a final iteration of said oxidizing treatment.

4. The method of claim 1, wherein said second recessing etch process also removes a third portion of said gate structure.

5. The method of claim 1, wherein said gate structure comprises a gate dielectric layer, a work function material layer positioned above said gate dielectric layer, and a conductive material layer positioned above said work function material layer, and wherein performing said oxidizing treatment comprises providing a first reactant gas for oxidizing material of said conductive material layer and providing a second reactant gas for oxidizing material of said work function material layer.

6. The method of claim 5, wherein said first reactant gas comprises oxygen, and said second reactant gas comprises chlorine.

7. The method of claim 1, wherein performing said second recessing etch process comprises providing a reactant gas including at least BCl₃.

8. The method of claim 7, wherein performing said second recessing etch process comprises providing a reactant gas further including Cl₂.

9. The method of claim 1, wherein performing said oxidizing treatment comprises performing said oxidizing treatment without a bias power being applied.

10. The method of claim 1, wherein said gate structure comprises a gate dielectric layer, and performing said second recessing etch process comprises removing at least a portion of said gate dielectric layer.

11. The method of claim 10, wherein performing said second recessing etch comprises applying a bias power.

12. A method, comprising:
forming a gate structure embedded in a dielectric layer above a substrate;
performing a first recessing etch process to remove a first portion of said gate structure;
performing an oxygen plasma treatment to oxidize a second portion of said gate structure after removing said first portion;
performing a second recessing etch process to remove at least said second portion to define a cap recess in said dielectric layer above said gate structure;
iteratively repeating said oxygen plasma treatment and said second recessing etch process to increase a depth of said cap recess; and
forming a cap layer in said cap recess.

13. The method of claim 12, further comprising performing a third recessing etch process to remove a third portion of said gate structure using a plasma comprising N₂, O₂, and NF₃ after performing a final iteration of said oxidizing treatment.

14. The method of claim 12, wherein said second recessing etch process also removes a third portion of said gate structure.

15. The method of claim 12, wherein said gate structure comprises a gate dielectric layer, a work function material layer positioned above said gate dielectric layer, and a conductive material layer positioned above said work function material layer, and wherein performing said oxygen plasma oxidizing treatment comprises providing a first reactant gas for oxidizing material of said conductive material layer and providing a second reactant gas for oxidizing material of said work function material layer.

16. The method of claim 15, wherein said first reactant gas comprises oxygen, and said second reactant gas comprises chlorine.

17. The method of claim 12, wherein performing said second recessing etch process comprises providing a reactant gas including at least BCl₃.

18. The method of claim 17, wherein performing said second recessing etch process comprises providing a reactant gas further including Cl₂.

19. The method of claim 12, wherein performing said oxidizing treatment comprises performing said oxidizing treatment without a bias power being applied.

20. The method of claim 12, wherein said gate structure comprises a gate dielectric layer, and performing said second recessing etch process comprises applying a bias power and removing at least a portion of said gate dielectric layer.
